(19) United States
(12) Patent Application Publication
(10) Pub. No.: US 2006/0134927 A1
(43) Pub. Date: Jun. 22, 2006

(54) Method for forming ultra thin oxide layer by ozonated water

(75) Inventors: Yung-Yu Chen, Hsinchu (TW); Kon-Tsu Kin, Hsinchu (TW); Chiou-Mei Chen, Hsinchu (TW); Jen-Chung Lou, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/303,938

(22) Filed: Dec. 19, 2005

(30) Foreign Application Priority Data
Dec. 21, 2004 (TW) 93139892

(51) Int. Cl. H01L 21/31; H01L 21/469

(52) U.S. Cl. 438/778

(57) ABSTRACT

The present invention relates to a method for forming an ultra thin oxide layer by using an ozonated water, which comprises the steps of dissolving an ozone-containing gas in deionized water to form an ozonated water, and immersing a silicon wafer in the ozonated water to from an ultra thin oxide layer on the wafer. The method according to the present invention can substitute for the conventional high temperature process for growing an ultra thin oxide layer and form an ultra thin oxide layer in high density and high uniformity by taking the advantages of time-saving, energy-saving but without conducting at an elevated temperature.

### FIELD OF THE INVENTION

The present invention relates to a method for forming an ultra thin oxide layer on a substrate, particular to a method for forming an ultra thin oxide layer on a substrate in high density and high uniformity without conducting at an elevated temperature.

### BACKGROUND OF THE INVENTION

In semiconductor process, to conform to Moore's law, it is necessary to reduce the size of devices from micrometer order to nanometer order with the advancing of the technology in this field. A thickness of oxide layer, such as a gate oxide layer, a dielectric layer in a DRAM storage capacitor, is also reduced from several tens nanometers to several nanometers, even reduced to less than 1 nanometer in future. How to grow an ultra thin oxide having excellent insulating property is a critical technical measure in semiconductor process. Among them, the quality of a gate oxide layer and a dielectric layer in a DRAM storage capacitor directly influences the yield of devices in semiconductor. Up to date, the ultra thin oxide is usually produced by a process of introducing oxygen or ozone gas into a high temperature furnace in which a substrate has been placed in and rapidly increasing and then rapidly decreasing the temperature of the chamber of the furnace to form an ultra thin oxide on the substrate. Alternatively, a chemical oxide layer is directly applied in a semiconductor process. However, the former process has disadvantages of long operation time, high energy requirement, and requires an apparatus resistant to high temperature and low pressure. Moreover, if it is intended to form an oxide layer in a thickness less than 1.5 nanometers, the process can not produce an oxide layer in a stiochiometry due to the presence of a transition layer which would reduce insulating property of the resultant oxide layer. As to the chemical oxide, it is not suitable for using as a gate oxide layer and a dielectric layer in a DRAM storage capacitor due to its low finesse.

U.S. Pat. No. 6,492,283 discloses a method of forming ultra thin oxide layer, comprising exposing a silicon substrate to an etching agent to remove native oxide from the substrate and simultaneously form ligands larger than hydrogen (H) or fluorine (F) on the substrate surface, and then forming an ultra thin oxide on the substrate surface by using strong oxidant including ozone.

U.S. Pat. No. 6,764,967 discloses a method for forming low thermal budget sacrificial oxides comprising forming a sacrificial oxide layer on the substrate by using a solution containing ozone and water, removing the sacrificial oxide layer by using etching agent to remove the silicon surface layer with high defecting concentration.

U.S. Pat. No. 6,737,302 discloses a method for forming an oxide layer by using ozonated water, the oxide layer is used as a stopping layer in etching a gate, a drain, and a source electrodes to simultaneously form a gate, a drain, and a source electrodes in one masking-exposing step.

U.S. Pat. No. 6,387,804 discloses a method for passivating the sidewall spacer of a gate electrode by using ozonated water.

The above mentioned references have no suggestion or teaching of forming ultra thin oxide layer as a gate oxide layer and a dielectric layer in a DRAM storage capacitor by using ozonated water.

### SUMMARY OF THE INVENTION

The main object of the present invention is to provide a method for forming an ultra thin oxide layer on a substrate by using ozonated water.

The other object of the present invention is to provide a method for forming a gate oxide layer and a dielectric layer in a DRAM storage capacitor by using ozonated water.

To attain the above objects, the present invention relates to a method for forming an ultra thin oxide layer by using an ozonated water, which comprises the steps of:

(a) contacting an ozonated water with a substrate, in which the ozonated water contains the ozone at a concentration of from 10 ppb to 20 ppm, preferably 0.5 to 10 ppm; and

(b) separating the substrate from the ozonated water, thereby an ultra thin oxide layer in a thickness of from 0.1 to 2.5 nm has been formed on the surface of the substrate.

### BRIEF DESCRIPTION OF DRAWINGS

FIG. 1 is a graph showing the relationship of the thickness of the ultra thin oxide layer formed by the present method in Example 1 vs. immersion time (oxidation time).

### DETAILED DESCRIPTION OF THE INVENTION

The term “ppb” means parts per billion and the term “ppm” means parts per million.

Preferably, the substrate used in the method according to the present invention includes, for example, a silicon substrate, an amorphous silicon substrate, a polysilicon substrate, a glass substrate, or a composite thereof, preferably a silicon substrate.

Preferably, the step (a) is conducted at a temperature of from 5 to 100° C., more preferably at room temperature.

Preferably, the step (a) is conducted in a period of from 10 seconds to 10 minutes.

Preferably, the present method further comprises a step of nitriding treatment of the surface of the substrate prior to step (a).

Preferably, the present method further comprises a step of nitriding treatment of the surface of the ultra thin oxide layer after step (b).

The ultra thin oxide layer formed by the present method can be used as a gate oxide layer in a semiconductor, an interfacial layer for high dielectric material, or an interfacial layer for a gate oxide layer in TFT-LCD

Ozone gas is easily decomposed into an oxygen free radical and oxygen gas. As diffusion rate and activity of the oxygen free radical is higher than oxygen molecular, using ozone as an oxidant for oxide layer can be applicable to a low temperature process (i.e., less than 300° C.) without lowering the growing rate of the oxide layer. The conventional method by using ozone gas as an oxidant for forming oxide layer in a thickness of less 1.5 nanometer is not easy to control the growing rate of the oxide layer. If it intends to obtain an oxide layer having uniform thickness, additional apparatus for raising and lowering temperature is required and thus the production cost is high. According to the method of the present invention, by contacting a medium to low concentration of ozonated water with a silicon surface, it is possible to form an oxide layer at relatively low temperature. By controlling the forming temperature at below 100° C., the diffusion rate of the oxygen free radical is greatly inhibited and can attain the purpose for forming an ultra thin oxide layer (<2.5 nanometer) having high uniformity and high density. The method of the present invention has advantages of time-saving, energy-saving, and conducting at an elevated temperature, and can form an ultra thin oxide layer (<2.5 nanometer) having high uniformity and high density. It can apply to the process for forming the ultra thin oxide layer used in wafer foundry, TFT-LCD, and DRAM electronic devices.

Since ozone is more active than oxygen, it easier reacts with silicon to form silicon dioxide at a low temperature or room temperature. As the diffusion rate in a relative low temperature is inhibited, it is easier to control the thickness of the oxide layer and thus can form an ultra thin oxide layer having high uniformity and high density. In a preferred embodiment of the present method, it comprises preparing ozonated water resulting from dissolving ozone in ultra pure water and then immersing a silicon wafer into the ozonated water. Especially, if a concentration of ozone in the ozonated water is less than 5 ppm and the method is conducted at a temperature near room temperature, the oxide forming rate would be decreased and thus can form an ultra thin oxide layer having high uniformity and high density.

### EXAMPLE 1

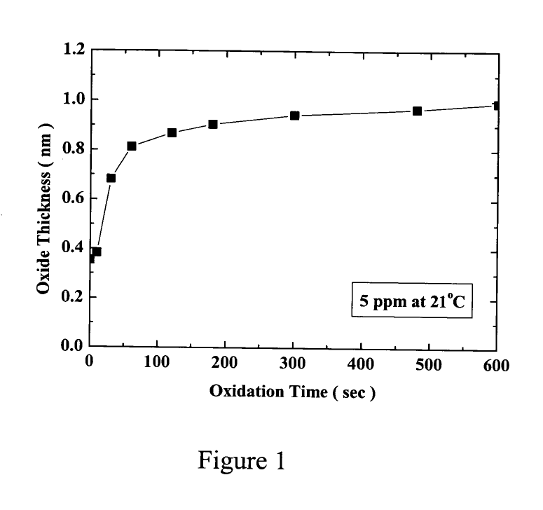

A silicon wafer (crystal orientation (100), P type substrate) was cleaned by a standard cleaning process usually used in semiconductor process (SPM+SC1+SC2, then remove the native oxide by using HF solution). The silicon wafer was immersed into a container containing 10 liters of ozonated water having an ozone concentration of 5 ppm at a temperature of 21° C. The ozonated water having an ozone concentration of 5 ppm was prepared by mixing ozone gas generated by ozonier with de-ionized water to form an ozonated water havinh high ozone concentration and then decreased the ozone concentration to 5 ppm by degassing. The thickness of the resultant oxide layer was measured by Elliposmeter and the relationship of the thickness of oxide layer with the immersion time (oxidation time) is shown in FIG. 1.

From the FIG. 1, it knows that at 30 seconds immersion an ultra thin oxide layer having a thickness of 0.68 nm was formed, and at 60 seconds immersion an ultra thin oxide layer having a thickness of 0.81 nm was formed. Thereafter, the growing rate of the oxide layer slows down.

### EXAMPLE 2

The procedures in Example 1 were followed except using ozonated water having an ozone concentration of 2 ppm. The results are similar to Example 1 but the thickness of the oxide layer at 120 seconds immersion time is less than that formed in Example 1.

What is claimed is:

1. A method for forming an ultra thin oxide layer by using an ozonated water, which comprises the steps of:
(c) contacting an ozonated water with a substrate, in which the ozonated water contains the ozone at a concentration of from 10 ppb to 20 ppm; and
(d) separating the substrate from the ozonated water, thereby an ultra thin oxide layer in a thickness of from 0.1 to 2.5 nm has been formed on the surface of the substrate.

2. The method according to claim 1, wherein the substrate used in the step (a) is a silicon substrate, an amorphous silicon substrate, a polysilicon substrate, a glass substrate, or a composite thereof.

3. The method according to claim 1, wherein the substrate used in the step (a) is a silicon substrate.

4. The method according to claim 1, wherein the concentration of ozone in the ozonated water in the step (a) is from 0.5 to 10 ppm.

5. The method according to claim 1, wherein the step (a) is conducted at a temperature of from 5 to 100° C.

6. The method according to claim 1, wherein the step (a) is conducted at a room temperature.

7. The method according to claim 1, wherein the step (a) is conducted in a period of from 10 seconds to 10 minutes.

8. The method according to claim 1, which further comprises a step of nitriding treatment of the surface of the substrate prior to step (a).

9. The method according to claim 1, which further comprises a step of nitriding treatment of the surface of the ultra thin oxide layer after step (b).

10. The method according to claim 1, wherein the ultra thin oxide layer is used as a gate oxide layer in a semiconductor, an interfacial layer for high dielectric material, or an interfacial layer for a gate oxide layer in TFT-LCD.
